(19) United States
(12) Patent Application Publication
(10) Pub. No.: US 2009/0195991 A1
(43) Pub. Date: Aug. 6, 2009

(54) Electric device having circuit board and casing and method for manufacturing the same

(75) Inventor: Mitsuteru Suzaki, Chiryu-city (JP)

Correspondence Address: HARNESS, DICKEY & PIERCE, P.L.C., P.O. BOX 828, BLOOMFIELD HILLS, MI, 48303, US

(73) Assignee: DENSO CORPORATION, Kariya-city (JP)

(21) Appl. No.: 12/321,121

(22) Filed: Jan. 15, 2009

(30) Foreign Application Priority Data
Feb. 6, 2008 (JP) 2008-026464

(51) Int. Cl. H05K 7/20; H01R 43/00

(52) U.S. Cl. 361/720; 29/592.1

(57) ABSTRACT

An electric device includes: a circuit board; an electric element on the board; a casing accommodating the board and including a receiving base and a protruding wall; and a heat radiation element between the board and the base. Heat conducts from the electric element to the casing via the board and the heat radiation element. The electric element is opposite to the heat radiation element across the circuit board. The base has a concavity and a through hole penetrating from the concavity to an outer surface of the casing. The wall surrounds the board. The height of the wall is larger than the height of the base, and smaller than the height of the board. The heat radiation element press-contacts in the concavity, protrudes from a clearance between the circuit board and the receiving base and a clearance between the circuit board and the protruding wall.

### CROSS REFERENCE TO RELATED APPLICATION

This application is based on Japanese Patent Application No. 2008-26464 filed on Feb. 6, 2008, the disclosure of which is incorporated herein by reference.

### FIELD OF THE INVENTION

The present invention relates to an electric device having a circuit board and a casing, and a method for manufacturing the same.

### BACKGROUND OF THE INVENTION

An in-vehicle electric device is mounted on a vehicle, and includes a circuit board, on which an electric element is disposed. The circuit board with the electric element is accommodated in a casing. The electric element includes, for example, a power transistor and an oscillator so that the electric element generates heat largely. In this case, the heat generated by the electric element is discharged to an outside of the casing. For example, the casing functions as a heat radiator, so that the circuit board is thermally connected to the casing. Thus, a heat radiation structure is formed.

The above heat radiation structure is disclosed in, for example, JP-A-2006-49501 and JP-A-2001-68607. To improve heat radiation property, a heat radiation member is sandwiched between the circuit board and the casing or between the electric element and the casing. The heat radiation member has flexibility. Thus, the circuit board and the casing or the electric element and the casing are densely connected to each other via the heat radiation member.

When the heat radiation member is sandwiched between the circuit board and the casing or between the electric element and the casing, if the heat radiation member is simply arranged between them, the heat radiation member may be displaced from an initial position so that the heat radiation property is reduced. Thus, in JP-A-2006-49501, the casing has a concavity or a convexity, which contacts the heat radiation member, so that the heat radiation member is accommodated in the concavity or the heat radiation member is hooked. Accordingly, the heat radiation member is not displaced.

However, in this structure, when the circuit board is fixed to the casing, the heat radiation member is compressed so that a load may be applied to the circuit board or the electric element. Thus, the stress may be applied to a solder portion.

In JP-A-2001-68607, the inner surface of the casing has a concavity arranged at a substantially center of the heat radiation surface of the casing, which contacts the heat radiation member. Alternatively, the surface of the casing contacting the heat radiation member has a concaved shape. Thus, when the circuit board is fixed to the casing, the volume of the heat radiation member to be compressed is reduced, so that the load to be applied to the circuit board is reduced.

However, in this structure, since the surface of the casing contacting the heat radiation member has the concavity or the concaved shape, the contact area between the heat radiation member and the casing is reduced so that the heat radiation property is reduced although the load to be applied to the circuit board and the electric element is reduced.

Thus, it is required to secure a sufficient contact area to reduce a load to be applied to the circuit board and the electric element.

### SUMMARY OF THE INVENTION

In view of the above-described problem, it is an object of the present disclosure to provide an electric device having a circuit board and a casing. It is another object to provide a method for manufacturing an electric device having a circuit board and a casing.

According to a first aspect of the present disclosure, an electric device includes: a circuit board having first and second surfaces; an electric element generating heat and arranged on the first surface of the circuit board; a casing accommodating the circuit board with the electric element, wherein the casing includes a receiving base and a protruding wall, both of which protrude from an inner bottom of the casing; and a heat radiation element sandwiched between the second surface of the circuit board and the receiving base of the casing. The heat radiation element conducts the heat from the electric element to the casing via the circuit board and the heat radiation element so that the heat is discharged to an outside of the casing. The electric element is disposed around a corner of the circuit board, and opposite to the heat radiation element across the circuit board. The receiving base has a concavity and a through hole. The through hole penetrates from the concavity to an outer surface of the casing. The protruding wall surrounds the circuit board, and is adjacent to the receiving base. The protruding wall has a height from the inner bottom, the receiving base has a height from the inner bottom, and the circuit board has a height from the inner bottom. The height of the protruding wall is larger than the height of the receiving base, and smaller than the height of the circuit board so that a clearance is provided between the circuit board and the protruding wall. The heat radiation element press-contacts in the concavity, protrudes from a clearance between the circuit board and the receiving base, and further protrudes from the clearance between the circuit board and the protruding wall.

In the above device, since the heat radiation element press-contacts in the concavity, protrudes from a clearance between the circuit board and the receiving base, and further protrudes from the clearance between the circuit board and the protruding wall, a load with the heat radiation element to be applied to the circuit board and the electric element is sufficiently reduced. Further, a sufficient contact area between the heat radiation element and the casing and a sufficient contact area between the heat radiation element and the circuit board are secured.

According to a second aspect of the present disclosure a method for manufacturing an electric device includes: preparing a casing having an attachment, a protruding wall and a receiving base, all of which protrudes from an inner bottom of the casing, wherein the attachment includes a screw hole, and the protruding wall is adjacent to the receiving base and connected to the attachment; forming a concavity and a through hole on the receiving base in such a manner that the through hole penetrates from the concavity to an outer surface of the casing and the concavity contacts the protruding wall; mounting an electric element on a first surface of a circuit board, wherein the electric element generates heat, and is arranged around a corner of the circuit board; mounting the circuit board with the electric element in the casing in such a manner that a heat radiation element is sandwiched between a second surface of the circuit board and the receiving base of the casing, and the electric element is opposite to the heat radiation element across the circuit board, wherein the second surface is opposite to the first surface; and fixing the corner of the circuit board on the attachment with a screw. The heat radiation element conducts the heat from the electric element to the casing via the circuit board and the heat radiation element so that the heat is discharged to an outside of the casing. The protruding wall surrounds the circuit board. The protruding wall has a height from the inner bottom, the receiving base has a height from the inner bottom, and the circuit board has a height from the inner bottom. The height of the protruding wall is larger than the height of the receiving base, and smaller than the height of the circuit board so that a clearance is provided between the circuit board and the protruding wall. The fixing the corner of the circuit board includes: press-contacting the heat radiation element in the concavity; protruding the heat radiation element from a clearance between the circuit board and the receiving base; and protruding the heat radiation element from the clearance between the circuit board and the protruding wall.

In the above method, since the heat radiation element press-contacts in the concavity, protrudes from a clearance between the circuit board and the receiving base, and further protrudes from the clearance between the circuit board and the protruding wall, a load with the heat radiation element to be applied to the circuit board and the electric element is sufficiently reduced. Further, a sufficient contact area between the heat radiation element and the casing and a sufficient contact area between the heat radiation element and the circuit board are secured.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram illustrating a main part of an electric device;

FIG. 2 is a diagram illustrating a circuit board before the circuit board is fixed to a casing;

FIG. 3 is a diagram illustrating a main part of the casing; and

FIG. 4 is a diagram illustrating a main part of the circuit board.

### DETAILED DESCRIPTION OF THE PREFERRED EMBODIMENTS

### First Embodiment

An electric device according to an example embodiment will be explained as follows. Here, the electric device is, for example, mounted on a vehicle so that the electric device functions as a communication device for transmitting and receiving information from an external information center. The communication device is connected to, for example, a vehicle navigation device, an air bag ECU or a security ECU so that the communication device informs the accident or the burglar of the vehicle together with the current position of the vehicle to the information center when an air bag opens and the air bag ECU detects the opening of the air bag, or when the vehicle is stolen and the security ECU detects the burglar.

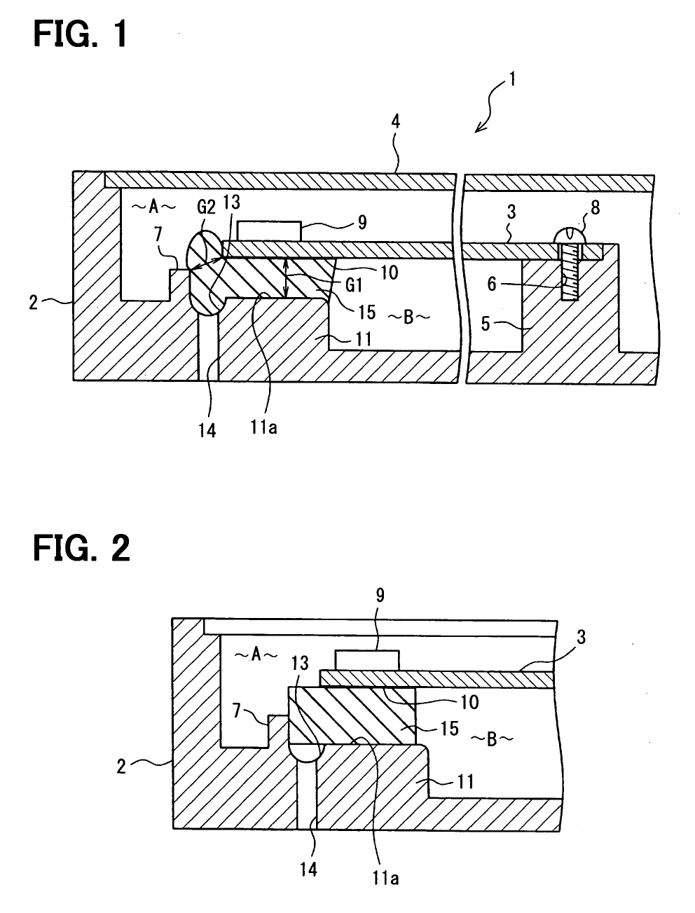

FIG. 1 shows a main part of the communication device 1. The communication device 1 includes a casing 2 and a circuit board 3, which is accommodated in the casing 2. The casing 2 is made of metal such as aluminum having high heat conductivity. The casing 2 has an opening, which is arranged on one side of the casing 2. The opening of the casing 2 is covered with a cover 4 made of metal such as iron.

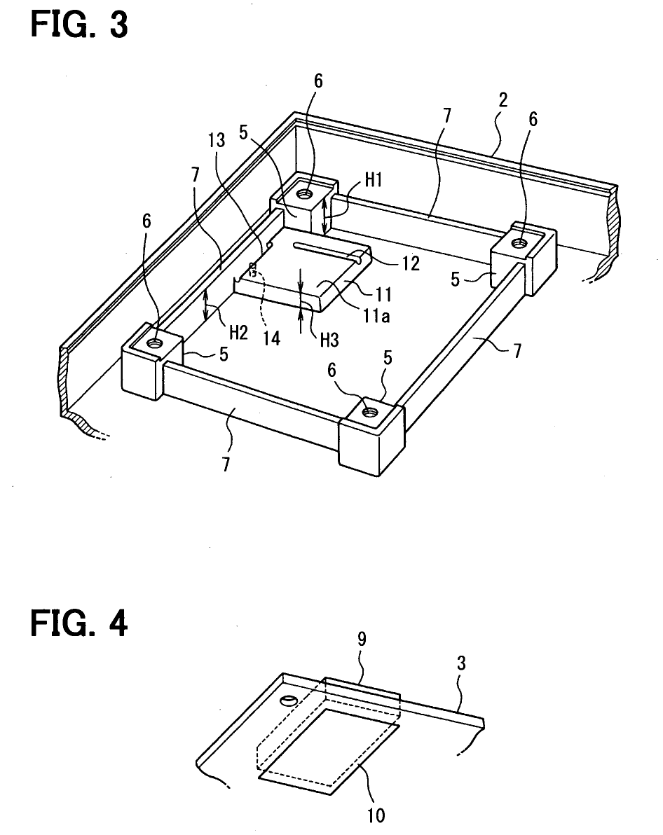

As shown in FIG. 3, the inner bottom of the casing 2 has four attachment members 5 for mounting the circuit board 3. Each corner of the circuit board 3 is mounted on a corresponding attachment member 5 of the casing 2. The circuit board 3 has a rectangular shape. Each attachment member 5 protrudes from the inner bottom of the casing 2. A screw hole 6 is formed in the attachment member 5. A rib 7 is formed on the inner bottom of the casing 2 so that the rib 7 connects four attachment members 5. The rib 7 functions as a electromagnetic wave shield of the circuit board 3. A rectangular area surrounded with the rib 7 is slightly larger than the circuit board 3. An electric element and/or an electronic element is mounted on the circuit board 3 so that the electric device provides the communication device 1. The circuit board 3 is mounted on the attachment members 5, so that the circuit board 3 is fixed to the attachment members 5 with a screw 8.

The electric element and the electronic element to be mounted on the circuit board 3 include an oscillator 9. The oscillator 9 oscillates so that the oscillator 9 generates heat. Therefore, it is necessary to cool the oscillator 9. Unless, the oscillator 9 may be down. To cool the oscillator 9, the device 1 has a cooling structure.

As shown in FIG. 4, the circuit board 3 has a fore side, on which the oscillator 9 is disposed. The circuit board 3 has a backside, on which a heat collection layer 10 made of, for example, a gold coating film is disposed. The back side of the circuit board 3 contacts the attachment members 5. The heat collection layer 10 is opposite to the oscillator 9. The oscillator 9 is disposed near one corner of the circuit board 3, and arranged on one side of the circuit board 3. A receiving base 11 having a rectangular shape is formed on the inner bottom of the casing 2. The receiving base 11 is protrudes from the inner bottom of the casing 2, and faces the heat collection layer 10. Thus, the receiving base 11 corresponds to the oscillator 9 on the circuit board 3.

One side of the receiving base 11 contacts one side of the attachment member 5, and anther side of the receiving base 11 contacts one rib 7, which is adjacent to the attachment member 5. The rib 7 provides a sidewall of the attachment members 5. The height of the attachment members 5, the height of the rib 7 and the height of the receiving base 11 from the inner bottom of the casing 2 has the following relationship that the attachment member 5 is the highest, the rib 7 is higher than the receiving base 11, and the receiving base 11 is the lowest. Here, the height of the attachment member 5 is defined as H1, the height of the rib 7 is defined as H2, and the height of the receiving base 11 is defined as H3. In view of the height relationship between the attachment member 5 and the receiving base 11, a clearance G1 is formed between the circuit board 3 and the receiving base 11 when the circuit board 2 is fixed to the attachment members 5 with the screw 8. Further, in view of the height relationship between the attachment members 5 and the rib 7 and in view of the relationship between the area surrounded with the rib 7 and the dimensions of the circuit board 3, a clearance G2 is formed between the circuit board 3 and the rib 7 when the circuit board 3 is fixed to the attachment members 5. The clearance G2 is disposed near the receiving base 11. The clearance G1 between the receiving base 11 and the circuit board 3 opens to a space A via the clearance G2. The space A is disposed over the circuit board 3 on a side of the circuit board 3. Further, the clearance G1 also opens to another space B since the receiving base 11 protrudes from the inner bottom of the casing 2. The other space B is disposed between the inner bottom of the casing 2 and the circuit board 3. Specifically, the clearance G1 opens to the other space B in three directions other than a rib side. The three directions direct from the receiving base 11 toward the other space B.

The receiving surface 11a of the receiving base 11, which protrudes from the casing 2 includes two concavities 12, 13, which provide a groove. One concavity 12 is in parallel to the one side of the attachment member 5. The other concavity 13 is in parallel to the rib 7. The other concavity 13 contacts the rib 7. Specifically, one side of the other concavity 13 on the rib side contacts the rib 7. A through hole 14 having a linear shape and extending from the other concavity 13 to the outer surface of the casing 2 is formed in the receiving base 11.

The heat radiation member 15 is sandwiched between the receiving base 11 and the circuit board 3. The heat radiation member 15 fills in the clearance G1 between the receiving base 11 and the circuit board 3 so that there is no space between the receiving base 11 and the circuit board 3. The heat radiation member 15 has high heat conductivity. In this embodiment, the heat radiation member 15 is made of soft material such as silicon rubber having flexibility. The heat radiation member 15 has a rectangular shape. The thickness of the heat radiation member 15 before the circuit board 3 is fixed to the attachment member 5 with the screw 8 is larger than the clearance G1 after the circuit board 3 is fixed to the attachment member 5 with the screw 8.

When the circuit board 3 is fixed to the attachment member 5, as shown in FIG. 2, the heat radiation member 15 is preliminarily mounted on the receiving base 11. Then, four corners of the circuit board 3 put on four attachment members 5, respectively, so that the circuit board 3 is fixed to the attachment members 5 with the screw 8. When the circuit board 3 is clamped on the attachment members 5 with the screw 8, the heat radiation member 15 is pressed by the circuit board 3 so that the heat radiation member 15 is sandwiched between the circuit board 3 and the receiving base 11. Thus, the heat radiation member 15 penetrates in the concavities 12, 13 of the receiving base 11. Further, the heat radiation member 15 densely contacts on both the receiving surface 11a of the receiving base 11 and the heat collection layer 10 of the circuit board 3.

Furthermore, the heat radiation member 15 is pressed so that the heat radiation member 15 becomes thin. By pressing the heat radiation member 15, a part of the heat radiation member 15 protrudes toward four directions in the horizontal direction. The part of the heat radiation member 15 protruding toward the three directions protrudes to the other space B, which surrounds the receiving base 11 in the three directions. The residual part of the heat radiation member 15 protruding toward the one direction is stopped by the rib 7 so that the heat radiation member 15 penetrates into the concavity 13 and protrudes to the space A via the clearance G2. After the circuit board 3 is fixed to the attachment members 5 with the screw 8, the cover 4 is fixed to the casing 2. After that, the heat radiation member 15 can be checked through the through hole 14. Specifically, the heat radiation member 15 is visible via the through hole 14 so that the heat radiation member 15 is properly assembled between the receiving base 11 and the circuit board 3. Thus, the existence of the heat radiation member 15 can be visibly checked via the through hole 14. Here, the receiving base 11 may include multiple through holes 14, which are in parallel to each other. The through holes provide to improve heat conduction from the space A and the space B to the outside of the casing 2. Specifically, the heat in the space A and B is effectively transmitted to the outside of the casing via the through holes.

The heat generated by the oscillator 9 conducts from the oscillator 9 to the casing 2 via the circuit board 3, the heat collection layer 10 and the heat radiation member 15 so that the heat is discharged to the outside of the casing 2, i.e., atmosphere.

In this embodiment, when the circuit board 3 is fixed to the casing 2, the heat radiation member 15 is sandwiched and pressed between the circuit board 3 and the receiving base 11, and the heat radiation member 15 protrudes to the concavities 12, 13 and the spaces A, B. Thus, solder portions in the oscillator 9 and the other electric elements and other electronic elements on the circuit board 3 are protected from being applied with a stress. Specifically, when the circuit board 3 is fixed to the casing 2, the heat radiation member 15 is not excessively compressed so that the reaction force of the compression deforms the circuit board 3 excessively.

Further, the rib 7 stops the protrusion of the heat radiation member 15 in the horizontal direction, so that the heat radiation member 15 easily penetrates into the concavities 12, 13. Specifically, the penetration of the heat radiation member 15 to the concavity 13 on the rib side is improved. Accordingly, the heat radiation member 15 sufficiently contacts the receiving base 11 in the concavities 12, 13, so that the heat from the oscillator 9 effectively conducts the casing 2 via the heat radiation member 15. Thus, the cooling performance is improved. Since the heat radiation member 15 penetrates into the concavities 12, 13, the penetrated portion of the heat radiation member 15 into the concavities 12, 13 functions as an anchor for preventing the heat radiation member 15 from being displaced. Further, even after the cover 4 is fixed to the casing 2, the heat radiation member 15 can be checked visibly via the through hole 14 when the electric device 1 is tested in a final test.

Although the electric device 1 is the communication device 1, the electric device 1 may be another device. Although the electric element for generating heat is the oscillator 9, the electric element may be a power device such as a power transistor.

The heat radiation member 15 may be formed by a package, in which liquid form material such as heat conductive grease or fluidity material is sealed.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. An electric device comprising:
a circuit board having first and second surfaces;
an electric element generating heat and arranged on the first surface of the circuit board;
a casing accommodating the circuit board with the electric element, wherein the casing includes a receiving base and a protruding wall, both of which protrude from an inner bottom of the casing; and
a heat radiation element sandwiched between the second surface of the circuit board and the receiving base of the casing,
wherein the heat radiation element conducts the heat from the electric element to the casing via the circuit board and the heat radiation element so that the heat is discharged to an outside of the casing,
wherein the electric element is disposed around a corner of the circuit board, and opposite to the heat radiation element across the circuit board,
wherein the receiving base has a concavity and a through hole,
wherein the through hole penetrates from the concavity to an outer surface of the casing,
wherein the protruding wall surrounds the circuit board, and is adjacent to the receiving base,
wherein the protruding wall has a height from the inner bottom, the receiving base has a height from the inner bottom, and the circuit board has a height from the inner bottom,
wherein the height of the protruding wall is larger than the height of the receiving base, and smaller than the height of the circuit board so that a clearance is provided between the circuit board and the protruding wall, and
wherein the heat radiation element press-contacts in the concavity, protrudes from a clearance between the circuit board and the receiving base, and further protrudes from the clearance between the circuit board and the protruding wall.

2. The electric device according to claim 1,
wherein the concavity contacts the protruding wall.

3. A method for manufacturing an electric device comprising:
preparing a casing having an attachment, a protruding wall and a receiving base, all of which protrudes from an inner bottom of the casing, wherein the attachment includes a screw hole, and the protruding wall is adjacent to the receiving base and connected to the attachment;
forming a concavity and a through hole on the receiving base in such a manner that the through hole penetrates from the concavity to an outer surface of the casing and the concavity contacts the protruding wall;
mounting an electric element on a first surface of a circuit board, wherein the electric element generates heat, and is arranged around a corner of the circuit board;
mounting the circuit board with the electric element in the casing in such a manner that a heat radiation element is sandwiched between a second surface of the circuit board and the receiving base of the casing, and the electric element is opposite to the heat radiation element across the circuit board, wherein the second surface is opposite to the first surface; and
fixing the corner of the circuit board on the attachment with a screw,
wherein the heat radiation element conducts the heat from the electric element to the casing via the circuit board and the heat radiation element so that the heat is discharged to an outside of the casing,
wherein the protruding wall surrounds the circuit board,
wherein the protruding wall has a height from the inner bottom, the receiving base has a height from the inner bottom, and the circuit board has a height from the inner bottom,
wherein the height of the protruding wall is larger than the height of the receiving base, and smaller than the height of the circuit board so that a clearance is provided between the circuit board and the protruding wall, and
wherein the fixing the corner of the circuit board includes:
press-contacting the heat radiation element in the concavity;
protruding the heat radiation element from a clearance between the circuit board and the receiving base; and
protruding the heat radiation element from the clearance between the circuit board and the protruding wall.
